(19) United States
(12) Patent Application Publication
(10) Pub. No.: US 2010/0032802 A1
(43) Pub. Date: Feb. 11, 2010

(54) Assembling of Electronic Members on IC Chip

(75) Inventors: Shinichi Togawa, Atsugi-shi (JP); Mutsumi Masumoto, Beppu-shi (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/539,122

(22) Filed: Aug. 11, 2009

(30) Foreign Application Priority Data
Aug. 11, 2008 (JP) 2008-206669

(51) Int. Cl. H01L 23/498; H01L 29/92; H01L 21/768; H01L 21/50

(52) U.S. Cl. 257/532; 257/737; 438/613; 438/120; 257/E23.068; 257/E29.342; 257/E21.589; 257/E21.499

(57) ABSTRACT

The objective of this invention is to provide an assembling method for electronic members characterized by the fact that electronic members can be joined reliably and easily without using solder paste. The semiconductor device of the present invention has the following parts: silicon substrate 100 with circuit elements formed on it, plural protrusion-shaped metal electrodes 110A, 110B formed on silicon substrate 100, and capacitor 140 having Au-plated electrodes 142, 144. The electrodes 142, 144 of capacitor 140 are metallurgically joined to protrusion-shaped metal electrodes 110A, 110B by means of ultrasonic thermo-compression bonding.

### FIELD OF THE INVENTION

The present invention pertains to assembling of electronic members on an IC chip or a silicon substrate. Especially, the present invention pertains to assembling of electronic members metallurgically joined to the surface of an IC chip.

### BACKGROUND OF THE INVENTION

In order to eliminate noise generated due to variation in the power voltage when power is turned ON, a bypass capacitor is connected to the outside of the semiconductor device. The capacitor can be attached to the circuit substrate where the semiconductor device is assembled. However, with this method, the assembly density of the circuit substrate cannot be increased. As a result, a semiconductor device containing a capacitor has been proposed.

For example, as shown in FIG. 1, Patent Reference 1 described the following scheme: an insulating sheet consisting of polyimide tape or the like is formed via an adhesive on semiconductor chip 1. On the upper surface of the insulating sheet, first conductor sheet 3 and second conductor sheet 4 consisting of Cu sheet are arranged side-by-side and are bonded by means of an adhesive. On the first conductor sheet 3 and second conductor sheet 4, chip capacitor 5 is attached by means of Ag-containing epoxy resin or another electroconductive adhesive. The two conductor sheets 3, 4 are connected to a ground electrode and power source electrode of semiconductor chip 1, respectively. The periphery of semiconductor chip 1 is sealed with a resin, and package main body 8 is formed.

FIGS. 2A, 2B, and 2C illustrate an example of a semiconductor device containing electronic members in the prior art. The semiconductor device shown in FIG. 2A has plural semiconductor chips formed as a module. On the back surface of multi-layer wiring substrate 10, plural ball-shaped bump electrodes 12 are formed. On the surface of the electrodes, plural conductor patterns 14 are formed and are electrically connected to bump electrodes 12, etc. The semiconductor chips 20, 22 are assembled on multi-layer wiring substrate 10 when bump electrodes on their back surface are connected to conductor patterns 14. In addition, on the surface of multi-layer wiring substrate 10, the electrode portions of electronic members 32, 34 are soldered by means of solder paste 30 to conductor patterns 14.

As shown in FIG. 2B, the semiconductor device is a resin sealed package with semiconductor chip 42 carried on a lead frame 40. On the lead frame 40, electrode portions of electronic member 46 are soldered by means of solder paste 44. Also, the electrode portions of electronic member 46 are electrically connected to electrodes of semiconductor chip 42 by means of wires 48 consisting of Au, Al, Cu or the like.

FIG. 2C includes a plan view and a side view of the semiconductor device using a bare die assembly substrate containing electronic members. Semiconductor chip 52 is assembled on IC assembly substrate or bare die assembly substrate 50. In addition, electronic members 54, 56 are soldered via solder paste 58 on assembly substrate 50. Conductor pattern 60 consisting of Cu or the like formed on bare die assembly substrate 50 is electrically connected to electrodes 64 of semiconductor chip 52 by means of wires 62 consisting of Au, Al, Cu or the like. The semiconductor chip 52 and electronic members 54, 56 on bare die assembly substrate 50 are covered with resin 66.

The semiconductor device containing electronic members in the prior art has electronic members soldered by means of solder paste, so it has the following problems. Due to lead-free solder, the wettability to the electrodes of an electronic member degrades. In addition, bad problems pertaining to storage stability, feeding stability and high melting point exist. Also, a step of operation should be present for formation of the solder paste by means of screen printing. Consequently, the cost rises. In addition, voids are generated in the joining portion, and a problem of residual liquid flux exists due to gas generated from the substrate. Especially, when voids are generated, poor electrical connection of the electronic members results, and the reliability degrades. In addition, due to poor joints, short circuits may occur due to bridging.

In addition, for the electronic members assembled on the semiconductor chip or assembly substrate, the attachment position of conductor patterns 14 is restricted due to the positioning, spacing and other relationships. Consequently, depending on the electronic member, the connection distance to conductor patterns 14 is lengthened, the electrical characteristics of the electronic member degrade, or noise is generated between the semiconductor chip and the electronic member. In order to alleviate degradation of the electrical characteristics and noise, new electronic members should be added, leading to an increase in the number of parts and an increase in cost.

The objective of the present invention is to solve the aforementioned problems of the prior art by providing a highly reliable semiconductor device characterized by the fact that electronic members can be joined with high reliability and easily without using solder paste.

In addition, another objective of the present invention is to provide a semiconductor device characterized by the fact that the electrical characteristics of the electronic members are stabilized, the size is miniaturized, and the cost is cut.

### SUMMARY OF THE INVENTION

The present invention provides a semiconductor device characterized by the following facts: the semiconductor device has a semiconductor substrate having plural circuit elements formed on it, plural protrusion-shaped metal electrodes, which are formed on the semiconductor substrate and which are electrically connected to selected elements of the plural circuit elements, and at least one electronic member with the following features: it is an electronic member having a first and a second electrode; the first electrode is metallurgically joined to a first protrusion-shaped metal electrode; the second electrode is metallurgically joined to a second protrusion-shaped metal electrode; and it is arranged on the semiconductor substrate; the first and second electrodes are connected to the first and second protrusion-shaped metal electrodes by means of ultrasonic thermo-compression bonding.

As a preferable scheme, each the protrusion-shaped electrode comprises an electrode, a Cu layer, and a palladium layer formed on the Cu layer; gold is plated on the first and second electrodes of the electronic member, and the metal joint comprises a gold-palladium eutectic. Also, as a preferable scheme, each the protrusion-shaped electrode comprises an electrode, a Cu layer, and a palladium layer formed on the Cu layer; Cu is plated on the first and second electrodes of the electronic member, and the metal joint comprises a Cu-palladium eutectic. In addition, each protrusion-shaped metal electrode may comprise a nickel layer between the Cu layer and palladium layer.

The following scheme may also be adopted: each protrusion-shaped metal electrode comprises a wiring layer that extends via an insulating film on the surface of the semiconductor substrate, and the first or second electrode is metallurgically joined to the extended wiring layer. As a preferable scheme, the first electrode is connected via the first extended wiring layer to a first electrode pad; the second electrode is connected via the second extended wiring layer to a second electrode pad; and a first electroconductive distance from the first electrode to the first electrode pad is equal to a second electroconductive distance from the second electrode to the second electrode pad. Also, the following scheme may be adopted: a space is formed between the electronic member and the surface of the semiconductor substrate, and the space is filled with an underfilling resin.

Also, the present invention provides a semiconductor device characterized by the fact that the semiconductor device has the following parts: a semiconductor substrate having plural circuit elements formed on it, plural protrusion-shaped metal electrodes, which are formed on the semiconductor substrate and which are electrically connected to selected elements of the plural circuit elements, with each of the protrusion-shaped metal electrodes having an electrode, a Cu layer formed on the electrode, and a palladium layer formed on the Cu layer, and at least one capacitor with the following features: it is at least one capacitor having a first and a second electrode; gold plating is applied on the first and second electrodes of the electronic member; the first and second electrodes are metallurgically joined to first and second protrusion-shaped metal electrodes by means of ultrasonic thermo-compression bonding; and it is arranged on the semiconductor substrate.

As a preferable scheme, the first electrode of the capacitor is electrically connected to the power source potential, and the second electrode is electrically connected to a reference potential. The space between the capacitor and the semiconductor substrate may be filled with an underfilling resin. Also, the plural protrusion-shaped metal electrodes may each comprise a bump electrode consisting of Au or Cu on a palladium layer. In addition, the plural protrusion-shaped metal electrodes may be arranged on an active region where the circuit elements are formed.

In addition, a space may be formed between at least one electronic member and the surface of the semiconductor substrate, and the space may be filled with an underfilling resin. Examples of assembled electronic members include capacitors, resistors, filters, and other members. For example, the capacitor may be a bypass capacitor connected to the power source potential and the reference potential. Also, it may be a capacitor for use in an A/D converter. Also, the system may have a package-on-package structure with the semiconductor substrate laminated on another semiconductor substrate. Also, the semiconductor substrate may be a resin package entirely sealed with a resin.

The present invention provides an assembling method for an electronic member characterized by the following facts: the method is for assembling an electronic member on a semiconductor chip; in this method, a semiconductor substrate with circuit elements formed on it is prepared; on the semiconductor substrate, plural protrusion-shaped metal electrodes are formed; each protrusion-shaped metal electrode has an electrode electrically connected to a circuit element, a Cu layer formed on the electrode, and a palladium layer formed on the Cu layer; while the electronic member is heated, the gold-plated electrodes of the electronic member are pressed on the plural protrusion-shaped metal electrodes as a precursory; ultrasonic vibration is applied to the electronic member; and the electrodes of the electronic member are metallurgically joined to the protrusion-shaped metal electrodes. As a preferable scheme, the ultrasonic vibration is turned ON when the electronic member reaches a first load, and the ultrasonic vibration is turned OFF when the electronic member reaches a second load.

### BRIEF DESCRIPTION OF THE DRAWINGS

FIG. 1 is a diagram illustrating an example of a semiconductor device containing a chip capacitor of the prior art.

FIG. 2A is a diagram illustrating another example of a semiconductor device containing an electronic member of the prior art.

FIG. 2B is a diagram illustrating another example of a semiconductor device containing an electronic member of the prior art.

FIG. 2C is a diagram illustrating another example of a semiconductor device containing an electronic member of the prior art.

FIG. 3A is a cross-sectional view illustrating a semiconductor device containing an electronic member in an embodiment of the present invention. FIG. 3B is an enlarged view of the protrusion-shaped metal electrodes.

FIG. 4 is an perspective view schematically illustrating a capacitor and protrusion-shaped metal electrodes.

FIGS. 5A, 5B, and 5C illustrate an example of the manufacturing operation for the protrusion-shaped metal electrodes in the present embodiment.

FIG. 6 is a diagram illustrating a wiring layer extending to a protrusion-shaped metal electrode.

FIG. 7 is a diagram illustrating a mounting device for mounting an electronic member.

FIG. 8A is a side view of a mounting head. FIG. 8B is an enlarged front view of the mounting head.

FIG. 9 is a diagram illustrating the relationship between pressure waveform, ultrasonic vibration and distance.

FIG. 10A is a diagram illustrating an example of a semiconductor device with assembling of electronic members in the present embodiment.

FIG. 10B is a diagram illustrating an example of a semiconductor device with assembling of electronic members in the present embodiment.

FIG. 10C and FIG. 10D illustrate an example of a semiconductor device with assembling of electronic members in the present embodiment.

FIG. 11 is a diagram illustrating an example of a semiconductor device having plural electronic members carried on it.

FIG. 12 is a cross-sectional view illustrating the main portion of the semiconductor device in Embodiment 2 of the present invention.

FIG. 13 is a cross-sectional view illustrating the main portion of the semiconductor device in Embodiment 3 of the present invention.

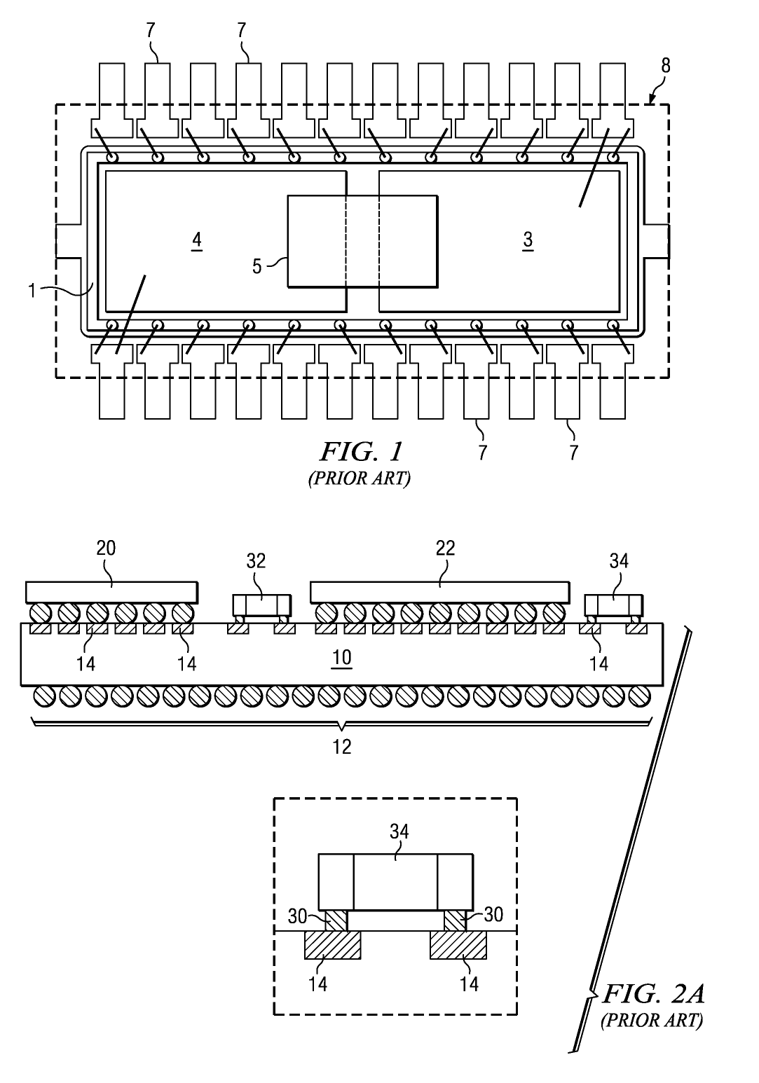

### REFERENCE NUMERALS AND SYMBOLS AS SHOWN IN THE DRAWINGS

In the figures, 100 represents a silicon substrate, 110A, 110B represent a protrusion-shaped metal electrode, 110C represents an extended wiring pattern, 120 represents an electrode pad, 122 represents a TiW/Cu barrier metal layer, 124 represents a Cu layer, 126 represents a nickel layer, 128 represents a palladium layer, 130 represents a protective film, 132 represents an opening, 140, 140A, 140B, 140C represent capacitors, 142 and 144 represent electrodes, 146 represents a main body portion, 148 represents a space.

### DESCRIPTION OF EMBODIMENTS

According to the present invention, the metal electrodes of the electronic member are metallurgically joined to protrusion-shaped metal electrodes formed on the semiconductor substrate or semiconductor chip for assembly. Consequently, the step of formation of solder paste on the substrate of the prior art is not required, so the cost of the semiconductor device can be reduced. Also, since soldering using a solder paste is not performed, poor connections due to generation of voids and generation of foam-like flux residue can be suppressed, and the reliability of joining of the electronic member can be improved. In addition, because the electrodes of the electronic member are connected to protrusion-shaped metal electrodes, the electrical connection distance from the electronic member to the electrodes on the substrate can be decreased, so generation of noise can be suppressed, and good electrical characteristics of the electronic member can be maintained. Especially, when plural electronic members are assembled, the various electrical connection distances can be identical, so that uniformity of the electrical characteristics of the various electronic members can be ensured. In addition, by connecting the electronic member to the protrusion-shaped metal electrodes, miniaturization of the semiconductor device can be promoted.

In the following, an explanation will be given in more detail regarding optimum embodiment of the present invention. Also, the figures are shown in an exaggerated way to facilitate explanation of the characteristic features of the present invention. The scale of the actual semiconductor devices may be different.

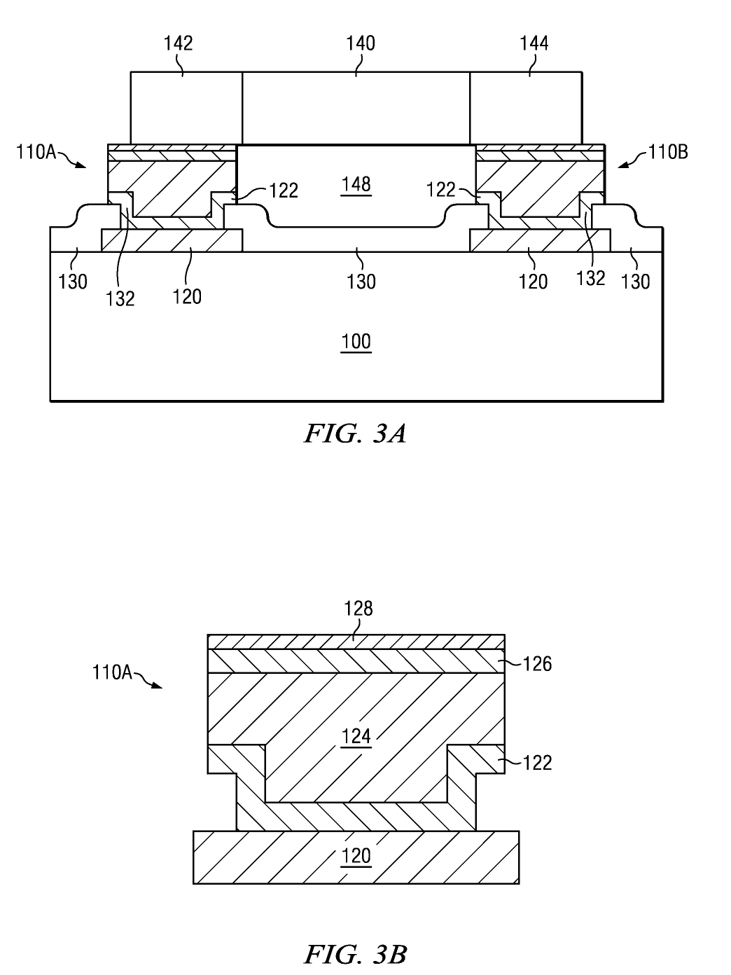

FIGS. 3A and 3B are cross-sectional views illustrating the main portion of a semiconductor device containing an electronic member pertaining to embodiment of the present invention. The semiconductor device in this embodiment comprises semiconductor substrate 100. On semiconductor substrate 100, plural circuit elements are formed. On the surface of semiconductor substrate 100, plural protrusion-shaped metal electrodes 110 are formed and electrically connected to the circuit elements. As shown in the figure, only two protrusion-shaped metal electrodes 110A, 110B are shown. In practice, more protrusion-shaped metal electrodes may be formed.

Because protrusion-shaped metal electrodes 110A, 110B have the same constitution, in the following, an explanation will be given regarding only protrusion-shaped metal electrode 110A. Here, protrusion-shaped metal electrode 110A preferably comprises electrode pad 120, TiW/Cu barrier metal layer 122, Cu layer 124, nickel layer 126 and palladium layer 128.

The electrode pad 120 consists of aluminum or an aluminum alloy. The electrode pad 120 is electrically connected to an underlying metal or polysilicon layer through a via hole not shown in the figure, or it is electrically connected to a diffusion region with a high impurity concentration formed on the surface of semiconductor substrate 100 through a contact hole. The surface of semiconductor substrate 100 is covered with a silicon oxide film or silicon nitride film or other protective film 130. On the protective film 130, opening 132 is formed to expose electrode pad 120. The TiW/Cu barrier metal layer 122 is connected through the opening 132 to electrode pad 120. On TiW/Cu barrier metal layer 122, patterned Cu layer 124, nickel layer 126 and palladium layer 128 are sequentially deposited.

On protrusion-shaped metal electrodes 110A, 110B, capacitor 140 with metallurgically joined electrodes is assembled. For example, the capacitor 140 is a tantalum ceramic capacitor. Gold plating is applied on the surface of electrodes 142, 144 on its two ends. The distance between electrodes 142, 144 of capacitor 140 corresponds to the spacing between protrusion-shaped metal electrodes 110A, 110B. The electrode 142 is metallurgically joined to protrusion-shaped metal electrode 110A, and the electrode 144 is metallurgically joined to protrusion-shaped metal electrode 110B. Here, the metal joint comprises a palladium-gold eutectic.

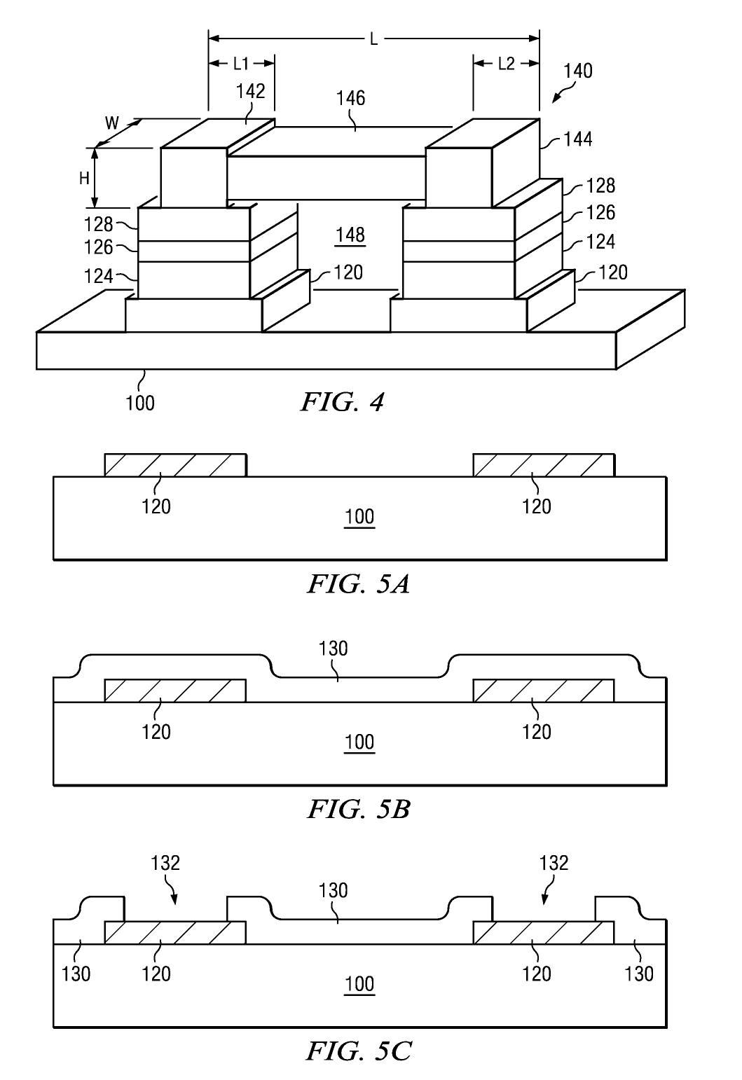

FIG. 4 is an perspective view schematically illustrating a capacitor and the protrusion-shaped metal electrodes. Here, capacitor 140 nearly has a rectangular shape, and the overall length L in the longitudinal direction is about 600 μm. Width W in the minor direction of electrodes 142, 144 is about 300 μm, and height H is about 300 μm. Lengths L1, L2 are about 100 μm. On the surface of electrodes 142, 144, Au plating is applied. The length of main body portion 146 between electrodes 142, 144 is 400 μm. Also, the height from the surface of the silicon substrate to palladium layer 128 is about 12 μm. A space 148 is formed between main body portion 146 of capacitor 140 and the silicon substrate. When space 148 is filled with an underfilling resin, capacitor 140 is reinforced.

The capacitor 140 is a bypass capacitor connected to the semiconductor device, and it removes noise due to variation in the power source voltage. In this case, electrode 142 on one side of capacitor 140 is connected via protrusion-shaped metal electrode 110A to the power source voltage, and electrode 144 on the other side of the capacitor is connected to the ground potential or reference potential via protrusion-shaped metal electrode 110B.

In the following, an explanation will be given regarding the method for forming the protrusion-shaped metal electrodes. An aluminum layer is formed over the entire surface of silicon substrate 100, and a conventional photolithographic operation is used to pattern electrode pad 120 as shown in FIG. 5A.

Then, as shown in FIG. 5B, protective film 130 consisting of SiO₂ or Si₃N₄ is formed to cover electrode pad 120. Then, using a mask not shown in the figure, protective film 130 is etched, and, as shown in FIG. 5C, openings 132 are formed on protective film 130 to expose electrode pad 120. Then, after removal of the mask, by means of CVD or sputtering, TiW, Cu, nickel and palladium are sequentially deposited, and an etching mask not shown in the figure is used to etch the layers from the palladium layer to TiW, forming protrusion-shaped metal electrodes 110A, 110B.

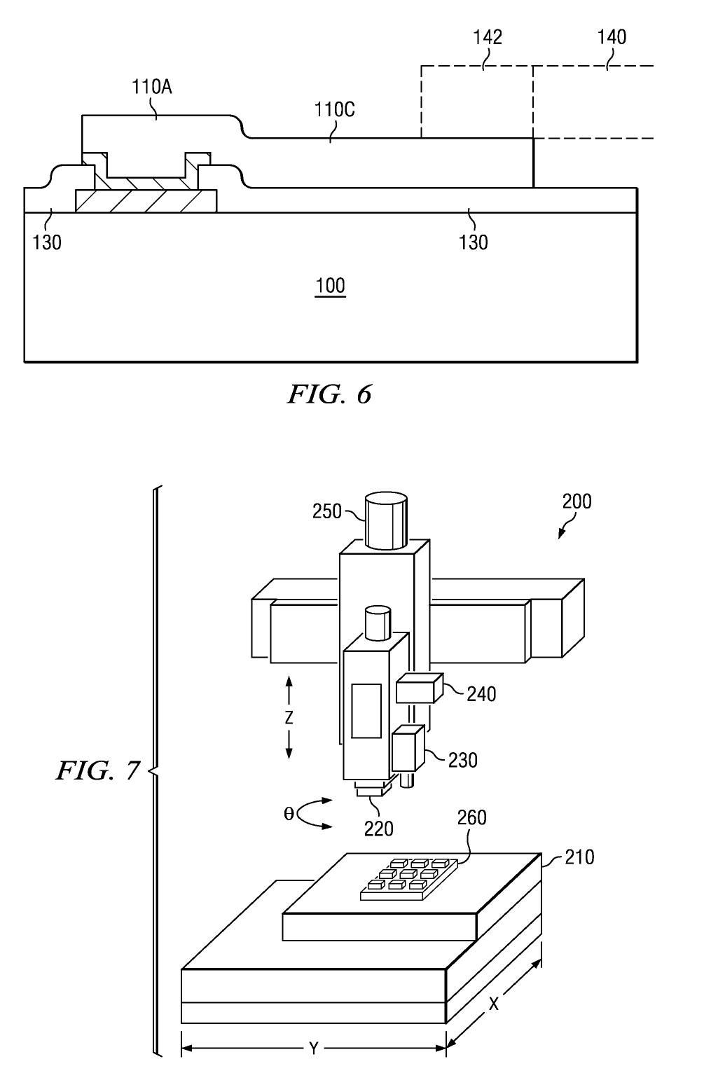

Also, as shown in FIG. 6, protrusion-shaped metal electrodes 110A, 110B may have wiring pattern 110C extending on protective film 130 except that it is formed extending in the vertical direction from the substrate shown in FIG. 3. The wiring pattern 110C comprises Cu layer 124, nickel layer 126 and palladium layer 128, and the width and length of wiring pattern 110C are determined corresponding to the shape of the assembled electronic member.

The protrusion-shaped metal electrodes 110A, 110B and wiring pattern 110C can be formed on the active region where circuit elements are formed on the semiconductor substrate. In addition, protrusion-shaped metal electrodes 110A, 110B and wiring pattern 110C can also be used as bonding pads in addition to assembling electronic members. With the use of direct bonding on electrode pad 120, a significant level of ultrasonic waves or load is applied on the circuit elements. However, because the protrusion-shaped metal electrodes 110A, 110B and wiring pattern 110C comprise Cu layer 124 on electrode pad 120, even when ultrasonic waves or load is applied on protrusion-shaped metal electrodes 110A, 110B and wiring pattern 110C, Cu layer 124 acts as a buffer material, and damage to the circuit elements can be suppressed.

Because protrusion-shaped metal electrodes 110A, 110B and wiring pattern 110C can be formed on the active region, restrictions on the assembly position of capacitor 140 are relaxed, and the freedom in position becomes very high. If the freedom of the assembly position of capacitor 140 is high, stabilizing of the electrical characteristics of capacitor 140 is promoted. That is, the electrical connection distance from electrodes 142, 144 of capacitor 140 to electrode pad 120 can be reduced, so that generation of noise can be suppressed. Also, when plural capacitors corresponding to plural channels of an A/D converter are assembled, for example, the electrical connection distances from the electrodes of the capacitors to the electrode pads are equal, and uniform electrical characteristics of the capacitors can be realized.

In the following, an explanation will be given regarding the assembling method for a capacitor. FIG. 7 is a diagram illustrating an example of an assembling apparatus for ultrasonic thermo-compression bonding of capacitors or other electronic members to a semiconductor chip. The apparatus 200 has the following parts: substrate stage 210 that allows sliding along the X-axis and Y-axis, mounting head 220 that performs assembling of a capacitor, recognition camera 230 that recognizes a semiconductor chip on substrate stage 210, load cell 240 that measures the load of mounting head 220, and motor 250 that drives to move mounting head 220 in the Z-axis direction and rotates it around the Z-axis by angle θ.

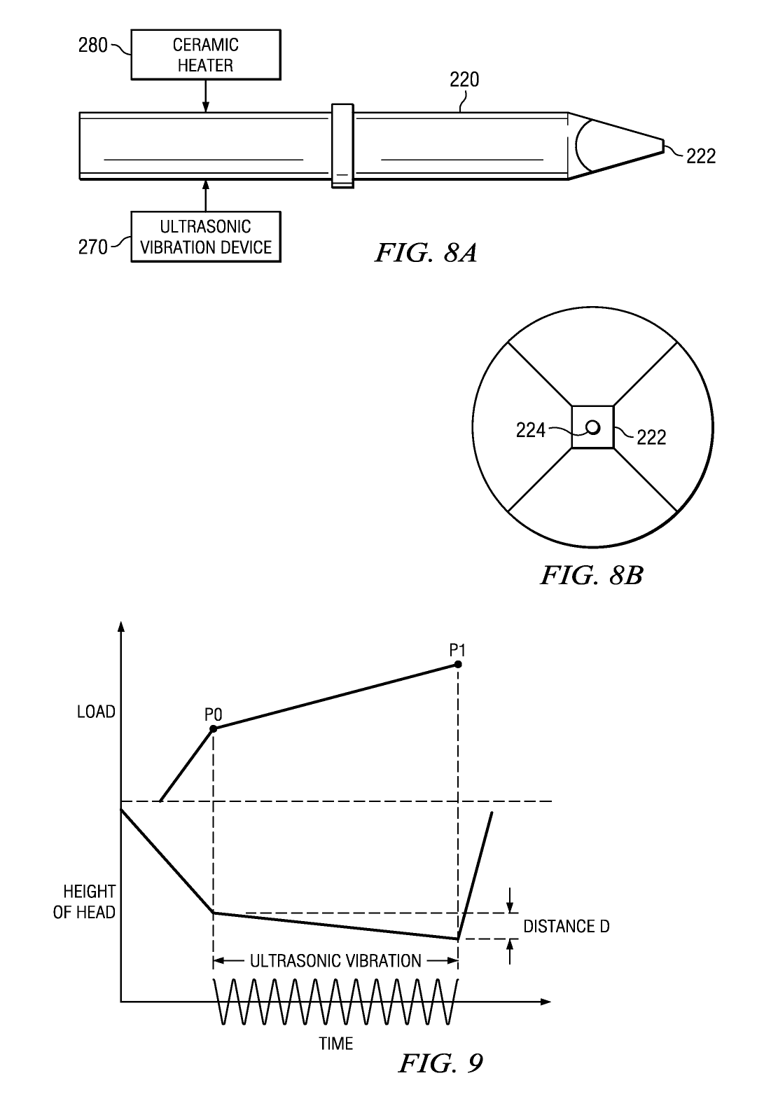

FIGS. 8A and 8B include an enlarged side view and a front view of the mounting head. The mounting head 220 consists of a cylindrical metal member extending in the axial direction. It has suction surface 222 for which the diameter gradually tapers smaller towards the tip. The suction surface 222 is a flat surface, with round hole 224 formed at its center. This hole 224 proceeds in the axial direction of mounting head 220, and it is connected to a suction device not shown in the figure. Also, ultrasonic vibration is applied on mounting head 220 from ultrasonic vibration device 270, and heat is applied from ceramic heater 280.

First, on substrate stage 210, chip tray 260 having plural semiconductor chips accommodated in it is carried. By driving substrate stage 210 to move in the X-direction or Y-direction, chip tray 260 is positioned.

Then, by means of motor 250, mounting head 220 is driven to move to a prescribed position. Here, when air is sucked through hole 224 on suction surface 222 of mounting head 220, a capacitor is held on suction surface 222. The mounting head 220 with a capacitor sucked on it is positioned on a semiconductor chip on substrate stage 210. Mounting head 220 is aligned by image processing of video data from recognition camera 230.

The mounting head 220 having a capacitor held on it is heated by heat from ceramic heater 280. As a result, the capacitor is held at about 170° C. Then, mounting head 220 presses with a prescribed load on the capacitor on protrusion-shaped metal electrodes 110A, 110B, and then ultrasonic vibration device 270 is used to apply ultrasonic vibration on mounting head 220.

As shown in FIG. 9, for mounting head 220, the following operation is preferred: when the load on mounting head 220 reaches P0, ultrasonic vibration is started, and, when the load on mounting head 220 reaches P1 higher than P0, the ultrasonic vibration is turned OFF. During the period of application of ultrasonic vibration, the height of mounting head 220 varies, and it is represented by distance D. That is, distance D represents the variation in height in the Z-axis direction of mounting head 220 during ultrasonic vibration. Because the distance D depends on the height and shape of the protrusion-shaped metal electrode, the period of ultrasonic vibration can be determined from a desired value for distance D. In this way, the electrodes of the capacitor are metallurgically joined to protrusion-shaped metal electrodes by means of ultrasonic thermo-compression bonding, forming a eutectic of Au and palladium.

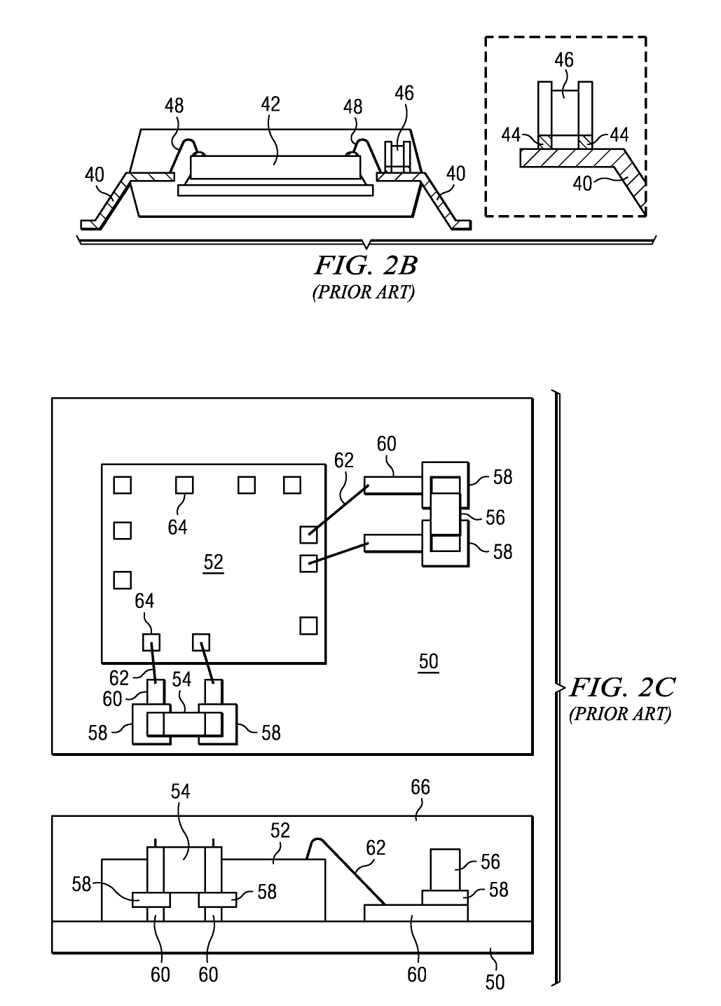

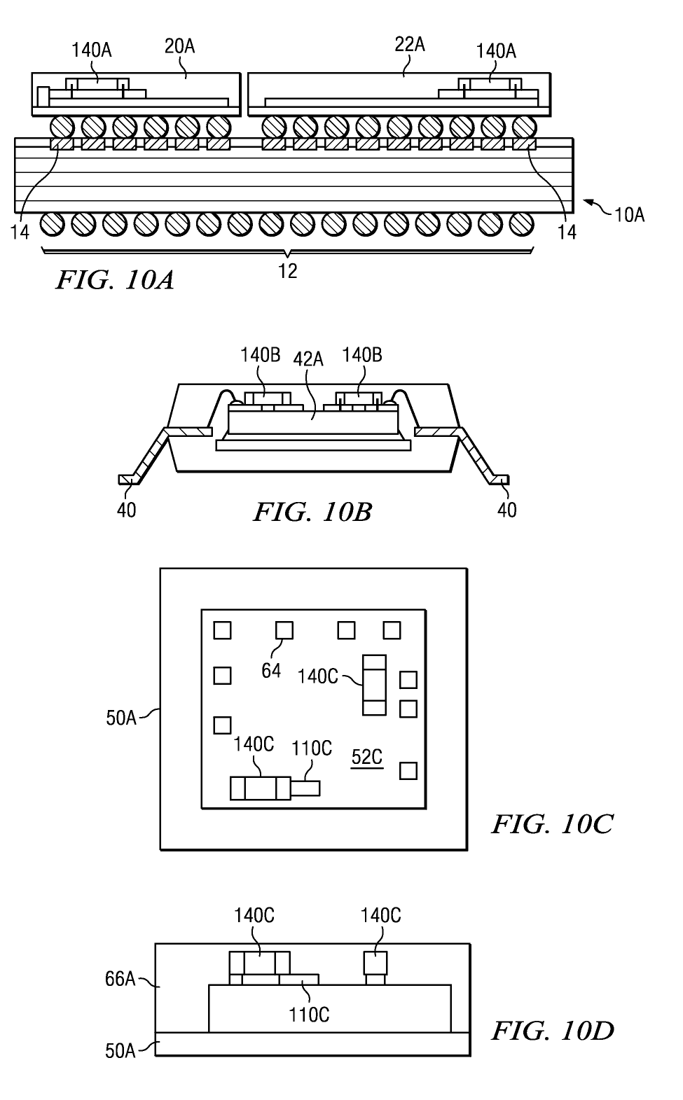

In the following, an explanation will be given regarding several examples of semiconductor devices pertaining to the present embodiment. FIG. 10A is a diagram illustrating the semiconductor device of the prior art shown in FIG. 2A adopted in the present embodiment. As shown in the figure, on semiconductor device 10A, semiconductor devices 20A, 22A are assembled. Capacitors 140A are metallurgically joined to protrusion-shaped metal electrodes formed on semiconductor devices 20A, 22A for assembly. As a result, the size of multi-layer wiring substrate 10A having semiconductor devices 20A, 22A assembled on it or of the module can be reduced. Also, soldering of the capacitor using a solder paste is not required as would be needed in the prior art, so the manufacturing operation can be simplified, and the cost can be cut.

FIG. 10B, corresponding to FIG. 2B, shows a semiconductor device sealed with molding resin. As shown in figure, capacitor 140B is mounted on protrusion shaped metal electrodes on the semiconductor chip by means of metal joining. As a result, it is possible to reduce the size of a resin package with a semiconductor chip sealed in it.

FIG. 10C is a diagram illustrating a semiconductor device corresponding to FIG. 2C. As shown in the figure, capacitors 140C are assembled on the surface of semiconductor chip 52A, followed by sealing with resin 66C. Also, in the example, one of the capacitors 140C is metallurgically joined to extending wiring pattern 110C. If a significant difference exists in the thermal expansion coefficient between the capacitor and the semiconductor substrate, the space between the capacitor and the semiconductor substrate may be filled with an underfilling resin, followed by sealing of the entirety with a resin.

FIG. 11 shows an example in which plural types of electronic members are carried on a semiconductor chip. Here, semiconductor device 300 comprises semiconductor chip 302 and plural external terminals 304, and, a plurality of protrusion-shaped metal electrodes formed on the surface of semiconductor chip 302 or wiring patterns extending from them are formed. The wiring patterns are arranged extending on the active region of the semiconductor chip. Selected electronic members 310-324 are metallurgically joined to selected protrusion-shaped metal electrodes or wiring patterns. Examples of the electronic members 310-324 include small core-type chip fixed resistors, tantalum capacitors, terminal EMI filters, IC protectors, etc.

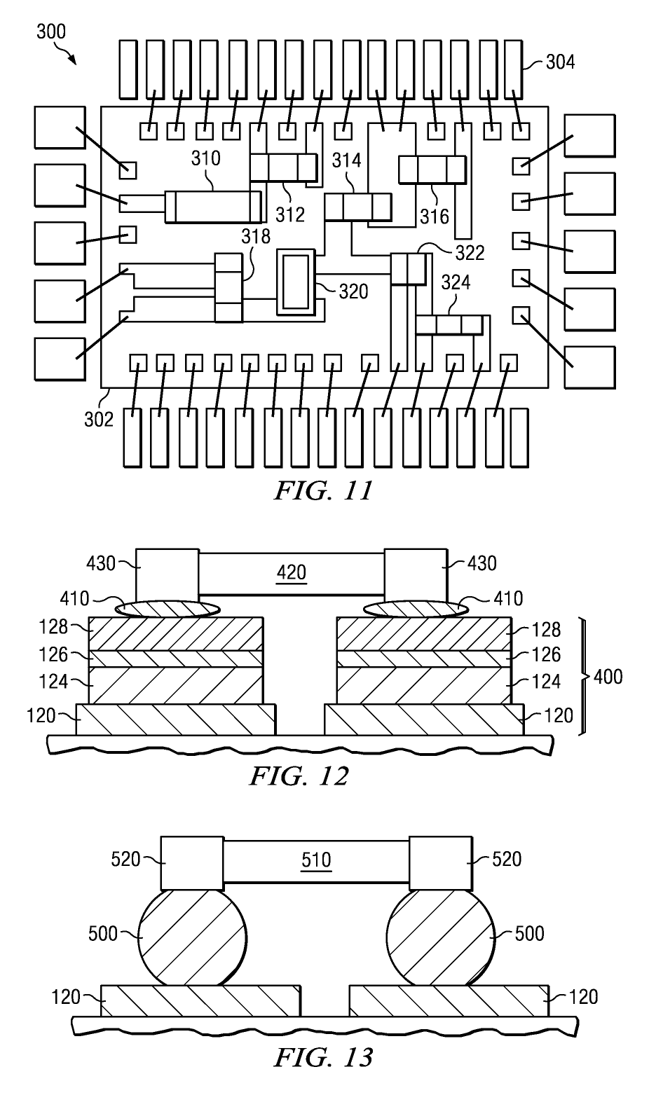

In the following, an explanation will be given regarding Embodiment 2 of the present invention. In Embodiment 2, as shown in FIG. 12, metal bumps 410 are formed on protrusion-shaped metal electrodes 400 comprising aluminum electrodes 120, Cu layers 124, nickel layers 126 and palladium layers 128. The metal bumps 410 are connected to metal-plated electrodes 430 of a capacitor or another electronic member 420 by means of ultrasonic thermo-compression bonding. The metal bumps 410 consist of a metal substance that can be metallurgically joined to protrusion-shaped metal electrodes 400 consisting of Au or Cu or the like. The metal plating of electrodes 430 consists of a metal substance that can form a metal eutectic with metal bumps 410 consisting of Au or Cu or the like.

In the following, an explanation will be given regarding Embodiment 3 of the present invention. In Embodiment 3, as shown in FIG. 13, on electrode pads 120 consisting of Al, bump electrodes 500 consisting of Au, Cu or another material are formed. Electrodes 520 of electronic member 510 are metal-plated with Au, Cu or another material that can form a metal eutectic with metal bumps 500.

In the above, preferable embodiments of the present invention have been explained in detail. However, the present invention is not limited to these schemes. For example, one may also adopt various modifications or changes as long as the gist of the present invention described in the claims is observed.

As a preferable structure of the protrusion-shaped metal electrodes, a palladium layer comprises the top layer, and a Cu layer is present between the palladium layer and the electrode pad. For example, a nickel layer may be present in the protrusion-shaped metal electrodes, or, in addition to the nickel layer, other metal layers may be present. The barrier metal layer is not limited to TiW/Cu. It may also be a TiW layer.

1. A semiconductor device, comprising:
a semiconductor substrate having plural circuit elements formed on it;
plural protrusion-shaped metal electrodes, which are formed on the semiconductor substrate and which are electrically connected to selected elements of the plural circuit elements; and
at least one electronic member including:
at least one electronic member having a first electrode metallurgically joined to a first protrusion-shaped metal electrode;
a second electrode is metallurgically joined to a second protrusion-shaped metal electrode; the first and the second protrusion-shaped metal electrode disposed on the semiconductor substrate; and
the first and second electrodes connected to the first and second protrusion-shaped metal electrodes by means of ultrasonic thermo-compression bonding.

2. The semiconductor device described in claim 1, in which the protrusion-shaped electrodes comprise an electrode, a Cu layer, and a gold-palladium eutectic layer on the Cu layer.

3. The semiconductor device described in claim 1, in which the protrusion-shaped electrodes comprise an electrode, a Cu layer, and a Cu-palladium eutectic layer on the Cu layer.

4. The semiconductor device described in claim 1, in which the protrusion-shaped metal electrodes comprise a nickel layer between a Cu layer and a eutectic alloy layer.

5. The semiconductor device described in claim 1, in which the protrusion-shaped metal electrodes comprise a wiring layer that extends via an insulating film on the surface of the semiconductor substrate, and the electrodes are metallurgically joined to the extended wiring layer.

6. The semiconductor device described in claim 5, in which the first electrode is connected via the first extended wiring layer to a first electrode pad; the second electrode is connected via the second extended wiring layer to a second electrode pad; and a first distance from the first electrode to the first electrode pad is equal to a second distance from the second electrode to the second electrode pad.

7. The semiconductor device described in claim 1, further comprising a space between at least one electronic member and the surface of the semiconductor substrate, and the space filled with an underfilling resin.

8. A semiconductor device, comprising:
a semiconductor substrate having plural circuit elements on it,
plural protrusion-shaped metal electrodes on the semiconductor substrate and electrically connected to selected elements of the plural circuit elements, with each of the protrusion-shaped metal electrodes having an electrode, a Cu layer formed on the electrode, and an eutectic palladium alloy layer on the Cu layer, and
at least one capacitor having a first and a second electrode with gold plating on a first and second electrodes metallurgically joined to first and second protrusion-shaped metal electrodes by means of ultrasonic thermo-compression bonding.

9. The semiconductor device described in claim 8, in which the first electrode of the capacitor is electrically connected to the power source potential, and the second electrode is electrically connected to a reference potential.

10. The semiconductor device described in claim 8, further comprising a space between the capacitor and the semiconductor substrate filled with an underfilling resin.

11. The semiconductor device described in any of claim 1, in which each of the plural protrusion-shaped metal electrodes comprises a bump electrode consisting of Au or Cu on a palladium layer.

12. The semiconductor device described in any of claim 11, in which the plural protrusion-shaped metal electrodes are disposed on an active region of the circuit elements.

13. The semiconductor device described in any of claim 12, in which the semiconductor substrate is disposed on another semiconductor substrate.

14. The semiconductor device described in any of claim 13, in which the semiconductor substrate is sealed with resin.

15. An assembling method for an electronic device including an electronic member on a semiconductor chip, comprising:
forming on the semiconductor substrate plural protrusion-shaped metal electrodes; each protrusion-shaped metal electrode having an electrode electrically connected to a circuit element,
forming a Cu layer on the electrode, and a palladium layer on the Cu layer;
heating the electronic member and pressing gold-plated electrodes of the electronic member on the plural protrusion-shaped metal electrodes;
applying ultrasonic vibration to the electronic member; and
metallurgically joining the electrodes of the electronic member to the protrusion-shaped metal electrodes.

16. The assembling method described in claim 15, further comprising turning the ultrasonic vibration on when the electronic member reaches a first load, and turning the ultrasonic vibration off when the electronic member reaches a second load.

17. The assembling method described in claim 15, in which the electrodes of the electronic member are joined to the protrusion-shaped metal electrodes by means of a gold-palladium eutectic.
